(19) United States
(12) Patent Application Publication
(10) Pub. No.: US 2016/0379943 A1
(43) Pub. Date: Dec. 29, 2016

(54) METHOD AND APPARATUS FOR HIGH PERFORMANCE PASSIVE-ACTIVE CIRCUIT INTEGRATION

(71) Applicant: SKYWORKS SOLUTIONS, INC., Woburn, MA (US)

(72) Inventors: Jerod F. Mason, Bedford, MA (US); David Scott Whitefield, Andover, MA (US); Dylan Charles Bartle, Arlington, MA (US); David T. Petzold, Chelmsford, MA (US)

(21) Appl. No.: 15/184,191

(22) Filed: Jun. 16, 2016

Related U.S. Application Data
(60) Provisional application No. 62/184,318, filed on Jun. 25, 2015.

(51) Int. Cl. H01L 23/66; H01L 21/84; H01L 27/12

(52) U.S. Cl. CPC H01L 23/66; H01L 27/1203; H01L 21/84; H01L 2223/6672; H01L 2223/6616

(57) ABSTRACT

An electronic device comprises an active radio frequency (RF) circuit element, and a passive RF circuit element integrated into the same silicon-on-insulation (SOI) substrate, and a dielectric carrier substrate bonded to the SOI substrate.

### CROSS-REFERENCE TO RELATED APPLICATION

This application claims priority under 35 U.S.C. §119(e) to U.S. Provisional Application Ser. No. 62/184,318 titled “METHOD AND APPARATUS FOR HIGH PERFORMANCE PASSIVE-ACTIVE CIRCUIT INTEGRATION,” filed Jun. 25, 2015, which is incorporated herein by reference in its entirety for all purposes.

### BACKGROUND

1. Field of Invention

The present invention relates generally to semiconductor devices, and methods for fabricating the same. More particularly, at least some embodiments are directed to silicon on insulator (SOI) devices including both active and passive components.

2. Discussion of Related Art

Silicon-on-Insulator (SOI) technology has been a core process for use in radio frequency (RF) circuits, particularly in high performance, low loss, high linearity switches. The performance advantage comes from building a transistor in silicon, which sits on an insulating buried oxide (BOX). The BOX sits on a handle wafer, typically silicon. High performance passive circuits used in radio frequency circuits (RF), particularly in high performance filters and couplers have been fabricated on high resistance substrates such as borosilicate glass, fused silica, high resistance silicon, and III-V materials such as GaAs due to higher resistance and lower dielectric constant of these substrates.

### SUMMARY OF INVENTION

At least some aspects and embodiments are directed to a semiconductor package and packaging process that that integrates active and passive elements of circuits, for example, radio frequency (RF) circuits, onto a single substrate so that the performance of both the active and passive elements in the circuit is optimized.

According to one aspect of the present invention there is provided an electronic device. The electronic device comprises an active radio frequency (RF) circuit element integrated into a silicon-on-insulator (SOI) substrate, a passive RF circuit element integrated into the SOI substrate, and a carrier substrate including a dielectric material bonded to the SOI substrate.

In some embodiments, the device further comprises a buried oxide layer. The active RF circuit element may be disposed on an upper surface of the buried oxide layer.

In some embodiments, the device further comprises a dielectric material layer formed above the active RF circuit element and the buried oxide layer. The passive RF circuit element may be disposed on an upper surface of the dielectric material layer. The passive RF circuit element may be laterally offset from the active RF circuit element.

In some embodiments, the dielectric material layer includes a plurality of interlayer dielectric material layers separating at least two layers of metal interconnects.

In some embodiments, the carrier substrate is bonded to the dielectric material layer.

In some embodiments, the device further comprises an adhesive layer bonding the carrier substrate to the dielectric material layer.

In some embodiments, the device further comprises a dielectric coating disposed on a lower surface of the buried oxide layer.

In some embodiments, the device further comprises a conductive via disposed in the dielectric coating and the buried oxide layer and in electrical contact with the active RF circuit element and with a contact formed on a lower surface of the dielectric coating.

In some embodiments, the carrier substrate is bonded to the buried oxide layer. The carrier substrate may be anodically bonded to buried oxide layer.

In some embodiments, the dielectric material is selected from the group consisting of fused silicon, borosilicate glass, III-V materials, sapphire, and high resistance silicon.

In some embodiments, the dielectric material is different from a material of a SOI carrier substrate upon which the electronic device was initially formed.

In some embodiments, the electronic device is incorporated into an RF system.

According to another aspect of the present invention, there is provided a method of forming an electronic device. The method comprises fabricating a silicon on insulator (SOI) device including an active radio frequency (RF) circuit element, a passive RF circuit element, a buried oxide layer, an interlayer dielectric material layer, and a semiconductor carrier substrate disposed on a lower surface of the buried oxide layer, bonding a dielectric carrier substrate to an upper surface of the interlayer dielectric material layer, removing the semiconductor carrier substrate from the SOI device, forming a protective dielectric material layer on the lower surface of the buried oxide layer, and forming a conductive via through the protective dielectric material layer and buried oxide layer, the conductive via electrically connecting the active RF circuit element to a contact formed on a lower surface of the protective dielectric material layer.

In some embodiments, the conductive via is formed through the buried oxide layer during fabrication of the SOI device and prior to removing the semiconductor carrier substrate from the SOI device.

In some embodiments, the conductive via is formed subsequent to removing the semiconductor carrier substrate from the SOI device.

In some embodiments, the conductive via is formed subsequent to forming the protective dielectric material layer.

In some embodiments, a conductive material of the conductive via is deposited in a same deposition step as the contact.

In some embodiments, bonding the dielectric carrier substrate to the upper surface of the interlayer dielectric material layer includes bonding the dielectric carrier substrate to the upper surface of the interlayer dielectric material layer with an adhesive material layer.

In some embodiments, the method further comprises incorporating the electronic device into an RF system.

According to another aspect of the present invention, there is provided a method of forming an electronic device. The method comprises fabricating a silicon on insulator (SOI) device including an active radio frequency (RF) circuit element, a passive RF circuit element, a buried oxide layer, an interlayer dielectric material layer, and a semiconductor carrier substrate disposed on a lower surface of the buried oxide layer, bonding a temporary carrier substrate to an upper surface of the interlayer dielectric material layer with a temporary adhesive, removing the semiconductor carrier substrate from the SOI device, bonding a dielectric carrier substrate to a lower surface of the buried oxide layer, and removing the temporary carrier substrate and temporary adhesive from the SOI device.

In some embodiments, bonding the dielectric carrier substrate to the lower surface of the buried oxide layer includes bonding the dielectric carrier substrate to the lower surface of the buried oxide layer with an adhesive.

In some embodiments, bonding the dielectric carrier substrate to the lower surface of the buried oxide layer includes anodically bonding the dielectric carrier substrate to the lower surface of the buried oxide layer. In some embodiments, bonding the dielectric carrier substrate to the lower surface of the buried oxide layer includes direct fusion bonding the dielectric carrier substrate to the lower surface of the buried oxide layer.

In some embodiments, the method further comprises incorporating the electronic device into an RF system.

### BRIEF DESCRIPTION OF DRAWINGS

Various aspects of at least one embodiment are discussed below with reference to the accompanying drawings. In the drawings, which are not intended to be drawn to scale, each identical or nearly identical component that is illustrated in various drawings is represented by a like numeral. For purposes of clarity, not every component may be labeled in every drawing. The drawings are provided for the purposes of illustration and explanation, and are not intended as a definition of the limits of the invention. In the drawings:

FIG. 1A is a cross-sectional side view of an example of a SOI circuit device;

FIG. 1B is a plan view of the SOI circuit device of FIG. 1A;

FIG. 2A illustrates a SOI circuit device upon which an example of a first method is performed;

FIG. 2B illustrates an act performed in the first method;

FIG. 2C illustrates another act performed in the first method;

FIG. 2D illustrates another act performed in the first method;

FIG. 2E illustrates another act performed in the first method;

FIG. 2F illustrates another act performed in the first method;

FIG. 3A illustrates a SOI circuit device upon which an example of a second method is performed;

FIG. 3B illustrates an act performed in the second method;

FIG. 3C illustrates another act performed in the second method;

FIG. 3D illustrates another act performed in the second method;

FIG. 3E illustrates another act performed in the second method;

FIG. 3F illustrates another act performed in the second method;

FIG. 4A illustrates a SOI circuit device upon which an example of a third method is performed;

FIG. 4B illustrates an act performed in the third method;

FIG. 4C illustrates another act performed in the third method;

FIG. 4D illustrates another act performed in the third method;

FIG. 4E illustrates another act performed in the third method;

FIG. 4F illustrates another act performed in the third method;

FIG. 5 is a block diagram of one example of a module including an RF circuit device according to aspects of the present invention;

FIG. 6 is a block diagram of one example of a wireless device including an RF circuit device according to aspects of the present invention; and

FIG. 7 is a block diagram showing a more detailed representation of one example of the wireless device of FIG. 6.

### DETAILED DESCRIPTION

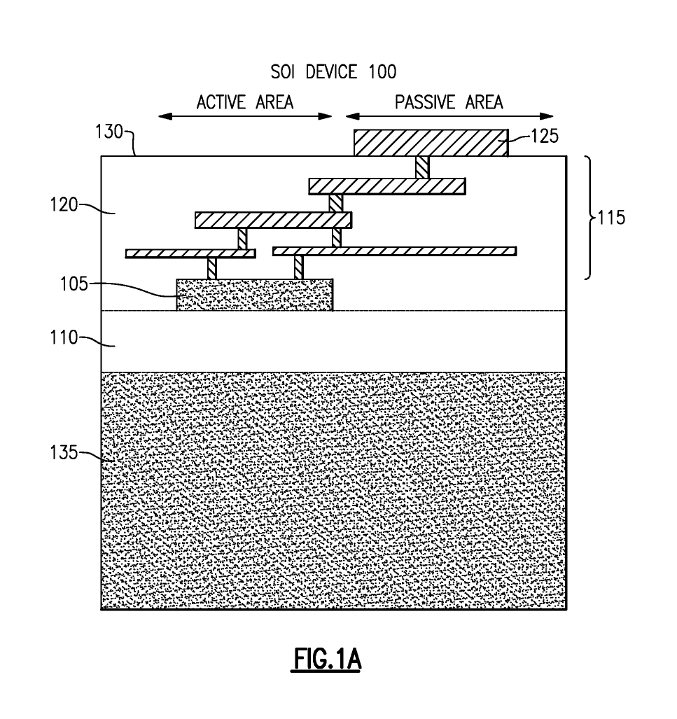

An example of a SOI device 100 including active and passive radio frequency (RF) circuit elements is illustrated in FIG. 1. As the terms are used herein, RF circuit elements or RF devices include circuit elements or devices that are configured to operate at frequencies in the radio frequency band and/or to process signals in the radio frequency band. FIG. 1 as well as the other figures included herein is highly simplified and schematic in nature and omits numerous features that the skilled artisan would recognize to be present in an actual electronic device. For example, the skilled artisan would recognize that embodiments of the devices disclosed herein may include additional circuit elements, interconnects, and external electrical contacts in addition to those illustrated.

SOI device 100 includes at least one active RF element formed in active semiconductor material 105. In one embodiment, the active semiconductor material 105 may include or consist of silicon. The active semiconductor material is disposed on a buried insulator layer, such as a buried silicon dioxide (BOX) layer 110. In one embodiment, the active semiconductor material 105 is in the form of an island as illustrated in FIG. 1. In one embodiment, the active RF element formed in the active semiconductor material 105 includes at least one transistor. In various embodiments, the active RF element may be formed with CMOS, bi-CMOS, or other types of transistors. In one embodiment, the active RF element includes an RF amplifier, filter, or switch, or one or more of a diode, field effect transistor, or varactor, although aspects and embodiments disclosed herein are not limited to including any particular active RF element.

A passive metal stack 115 is formed in an interlayer dielectric material layer 120. The interlayer dielectric material layer 120 includes multiple layers of a dielectric material, for example, silicon dioxide that separates the various metal layers in the passive metal stack 115. The passive metal stack 115 electrically connects the active RF element formed in active semiconductor material 105 to at least one passive RF element 125 and, in some embodiments, to additional active RF elements (not shown). The passive RF element 125 includes any one or more of a capacitor, an inductor, a resistor, a conductive trace, a coupler, a matching network, or any other passive element known in the art. The passive RF element 125 is disposed on a top surface 130 of the interlayer dielectric material layer 120. In some embodiments, the passive RF element 125 can be created from some portion or all of the metal layers in metal stack 115 plus element 125, not just element 125 alone. The SOI device 100 may thus include a passive area laterally offset from an active area as indicated in FIG. 1.

The thickness from the bottom surface of the buried silicon dioxide layer 110 to the top surface 130 of the interlayer dielectric material layer 120 and/or the top surface of the passive RF element 125 may be as small as about 10 microns (μm) or less. To provide mechanical stability, a SOI carrier substrate 135 or handle wafer is bonded to the bottom of the buried silicon dioxide layer 110. In one embodiment the SOI carrier substrate 135 includes or consists of silicon, for example, in the form of a silicon wafer. In some embodiments, SOI “starting wafers” including preformed layers 135, 110, and 105 may be provided from a supplier. In other embodiments, the buried silicon dioxide layer 110 is formed by oxidizing a top surface of the SOI carrier substrate 135. In another embodiment, the buried silicon dioxide layer 110 is formed by ion implanting oxygen through an upper surface of the SOI carrier substrate 135, heat treating the SOI carrier substrate 135, and etching away portions of the upper surface of the SOI carrier substrate 135, leaving an island of active semiconductor material 105. In one embodiment, the SOI carrier substrate 135 is significantly thicker than the other layers of the SOI device 100, for example, having a thickness of between about 500 μm and about 800 μm.

The skilled artisan will recognize that in various embodiments various modifications may be made to SOI device 100. For example, the active semiconductor material 105 need not include or consist of silicon. In some embodiments, other semiconductor materials, for example, gallium arsenide and/or indium phosphate may alternatively or additionally be employed. The active semiconductor material 105 need not be formed as an island as illustrated in FIG. 1, but rather may extend as a layer substantially or completely covering the buried oxide layer. The passive RF element 125 may, in some embodiments, be embedded in the interlayer dielectric material layer 120 rather than disposed on the top surface 130 thereof or alternatively, may be located in another portion of the SOI device.

It has been discovered that when integrating active and passive RF circuit elements onto a single SOI chip including a silicon carrier substrate or handle wafer, the performance of the passive elements is often degraded due to the proximity of the silicon handle wafer to the passive elements, as well as due to the resistance and dielectric properties of the involved materials. It has been observed that passive RF elements formed in a SOI chip including a silicon handle wafer may capacitively couple to the silicon handle wafer. In some embodiments, the capacitive coupling may be through the meal layers in the passive metal stack 115. The capacitive coupling between the passive RF element(s) and the silicon handle wafer may be non-linear in nature. For example, the effect of this capacitive coupling may in some instances change (for example, increase) with frequency, voltage, and/or with conductivity of the silicon handle wafer. The capacitive coupling between the passive RF element(s) and the silicon handle wafer may in some instances cause harmonics of an RF signal in or passing through the passive RF element(s) to develop in the passive RF element(s), decreasing the quality of the RF signal. Various aspects and embodiments disclosed herein provide methods for integrating the active and passive RF elements of an RF circuit onto a single substrate so that the performance of both the active and passive RF elements in the RF circuit are optimized, or at least improved as compared to similar RF circuits mounted on a silicon handle wafer as illustrated in FIG. 1.

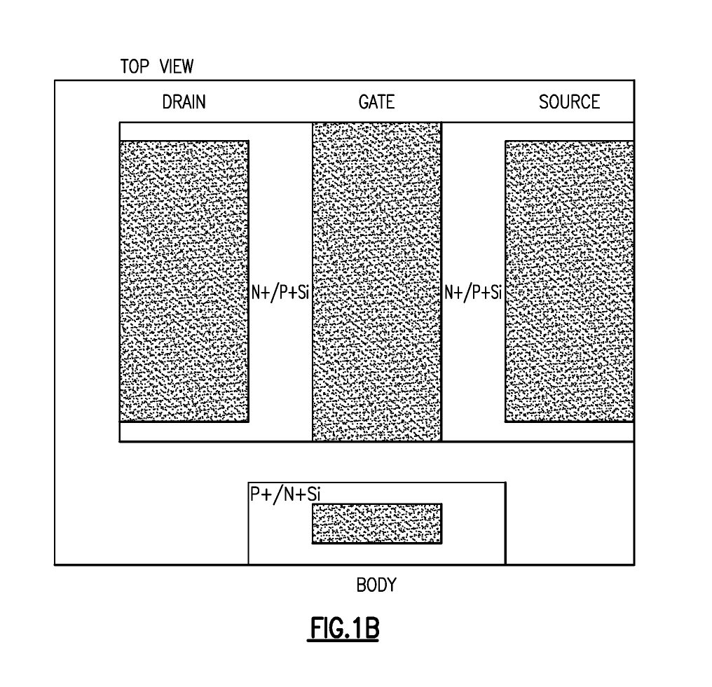

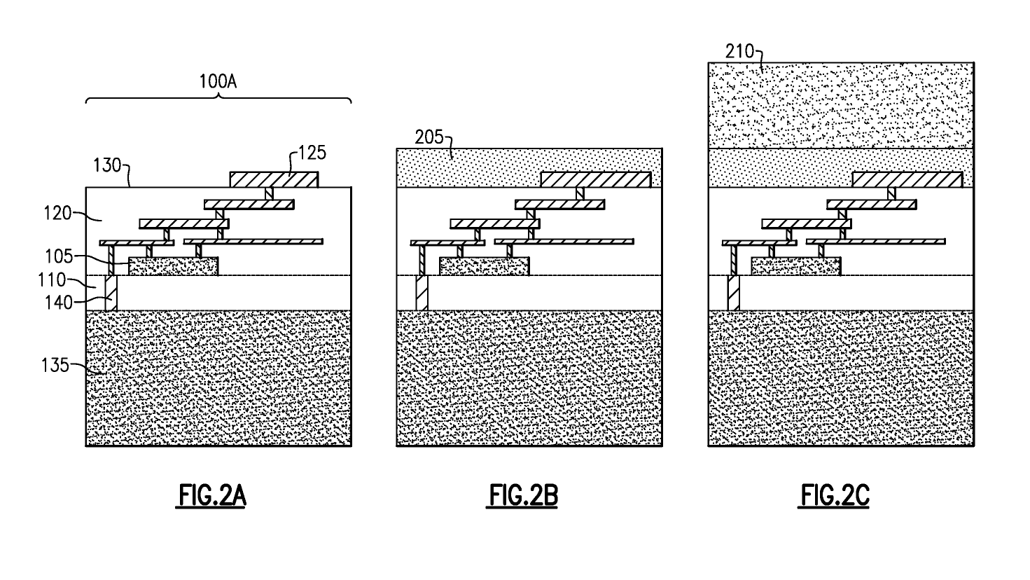

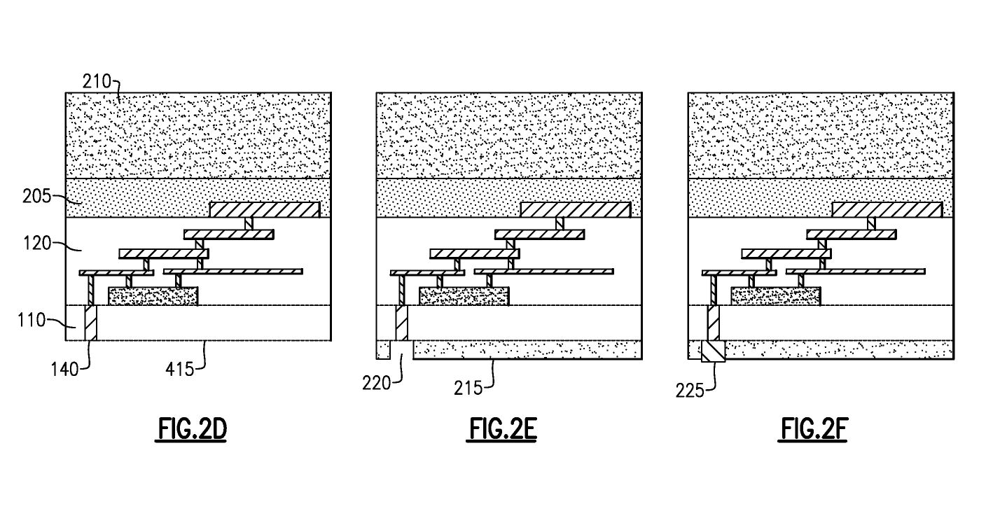

A first method disclosed herein includes a single layer transfer process which permanently bonds a carrier substrate to the front side of a wafer on which RF circuits are formed, followed by the removal of the original silicon handle wafer. An example of this single layer transfer process is depicted in FIGS. 2A through 2F. The starting wafer in these figures has been formed through standard front side SOI processing techniques and includes RF circuits similar to that illustrated in FIG. 1. As such, the same reference numbers used in FIG. 1 to illustrate the various portions of the SOI device 100 are also used to indicate similar portions of the RF circuit device 100A in FIGS. 2A through 2F as well as in the figures illustrating the other methods disclosed herein. In the figures illustrating the methods disclosed herein only a single RF circuit portion of a wafer is illustrated. The skilled artisan will understand that a single wafer may include thousands or even millions or more of the single RF circuit portions illustrated in the figures. The starting wafer includes circuits that have both active and passive elements as well as conductive through BOX vias 140 (one of which is illustrated in FIGS. 2A-2F) including a via hole filled with metal, polysilicon, or other conductive material.

After completion of the fabrication of the RF circuit devices 100A on a wafer, the wafer is coated with a uniform, planar low dielectric constant adhesive 205 as depicted in FIG. 2B. In some embodiments, the low dielectric constant adhesive 205 has a dielectric constant of between about 2 and about 5. The adhesive 205 is applied to the upper surface 130 of the interlayer dielectric material layer 120 and of the passive RF element 125. In some embodiments, the adhesive comprises, for example, a photoimageable polyimide or a photoimageable silicone based material. The adhesive 205 can be patterned using standard photolithography techniques as needed to reduce stress and/or to assist in solvent extraction during wafer bonding. The front side of the SOI wafer is then permanently wafer bonded to a carrier substrate 210, as illustrated in FIG. 2C, using a wafer bonding tool set and methods known in the art. Multiple types of carrier substrates 210 are available and include fused silicon, borosilicate glass, III-V materials, sapphire, and high resistance silicon. In some embodiments, if silicon is used for the carrier substrate 210 it may have a resistivity of greater than about 1 kΩ-cm. In some embodiments, the carrier substrate 210 has a dielectric constant of between about 2 and about 5. The passive RF element(s) 125 of the RF circuit device 100A exhibit a lesser degree of capacitive coupling (if any) and/or a lesser degree of non-linear interaction with the carrier substrate 210 than with the original SOI carrier substrate 135. The linearity and loss of the passive RF element(s) 125 of circuits can be improved with the careful selection of a low dielectric constant adhesive 205 and carrier substrate 210. The thickness of the adhesive 205 can be modified to adjust the proximity of the passive element 125 to the carrier substrate 210 and thus can be used to optimize capacitive coupling between the passive RF element 125 and the carrier substrate 210. In some embodiments, the thickness of the adhesive 205 can range from about 4 μm to over about 60 μm, the BOX layer 110 thickness can range from about 0.1 μm to about 2 μm and the carrier substrate 210 may range in thickness from about 500 μm to about 800 μm.

The capacitance between the active RF element(s) 105 of the RF circuit device 100A and the other elements of the RF circuit device 100A can then be reduced by removing the original SOI carrier substrate 135. The SOI carrier substrate 135 portion of the SOI wafer can be removed by one or more of grinding, chemical mechanical polishing (CMP), and/or selective etching using an appropriate chemistry as shown in FIG. 2D. The removal of the SOI carrier substrate 135 exposes the BOX layer 110 of the RF circuit device 100A and the localized through BOX vias 140. The lower surface 415 of the BOX layer 110 can then be coated with a protective coating layer 215 including one or more materials, for example, silicon nitride, polysilicon, and low K dielectrics or mixtures thereof to bind the parasitic surface charge on the BOX layer 110 and to provide a protective coating to prevent moisture ingress and provide physical protection of the device as shown in FIG. 2E. A through layer via hole 220 is defined in the protective coating layer 215 by, for example, conventional lithographic and etch processes or by selective deposition of the protective coating layer 215. Contacts 225 (one of which is illustrated in FIG. 2F) are then formed in, and, in some embodiments, below the via hole 220 to contact the through BOX vias 140. Contacts 225 may be formed by physical or chemical deposition processes, electroplating, or any metal deposition process known in the art. Contacts 225 are used to connect the elements of the RF circuit device 100A to outside circuit elements.

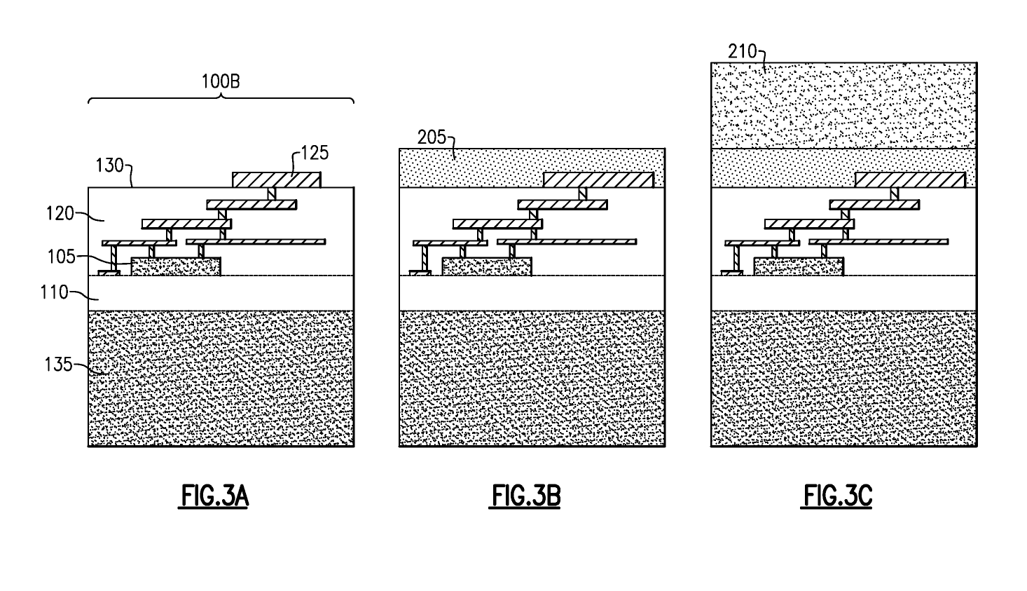

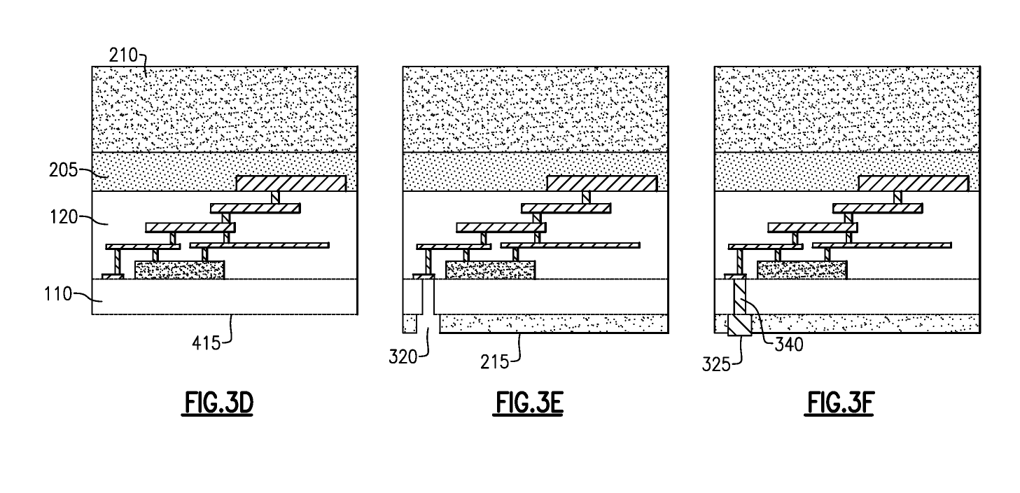

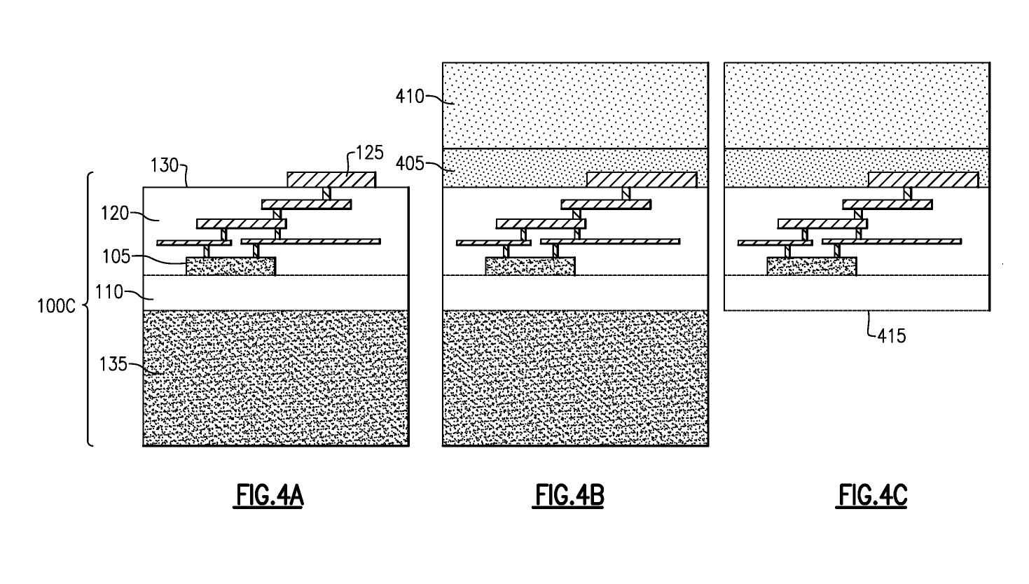

A second method disclosed herein also uses a single layer transfer process, but the through BOX via(s) are formed after the layer transfer process. An example of a method used for this alternative single layer transfer process is depicted in FIGS. 3A through 3F. As shown in FIG. 3A, the starting wafer in these figures has again been formed through standard front side SOI processing techniques and includes RF circuit devices 100B similar to those illustrated in FIG. 1. The wafer is coated with a uniform, planar low dielectric constant adhesive 205 as shown in FIG. 3B. There are multiple types of appropriate adhesives including photoimageable polyimide and photoimageable silicone based materials. The adhesive 205 can be patterned using standard photolithography techniques as needed to reduce stress and/or to assist in solvent extraction during wafer bonding. The front side of the SOI wafer is then permanently wafer bonded to a carrier substrate 210, as shown in FIG. 3C, using a known wafer bonding tool set. Multiple types of carrier substrates are available and include fused silicon, borosilicate glass, III-V materials, sapphire, and high resistance silicon. The passive RF element(s) 125 of the RF circuit device 100B exhibit a lesser degree of capacitive coupling (if any) and/or a lesser degree of non-linear interaction with the carrier substrate 210 than with the original SOI carrier substrate 135. The linearity and loss of the passive RF element(s) 125 of circuits can be improved with the careful selection of a low dielectric constant adhesive and carrier substrate. The thickness of the adhesive 205 can be modified to adjust the proximity of the passive RF element 125 to the carrier substrate 210 and thus be used to optimize capacitive coupling between the passive RF element 125 and the carrier substrate 210.

The capacitance between the active RF element(s) 105 of the RF circuit device 100B and other elements of the RF circuit device 100B can then be reduced by removing the original SOI carrier substrate 135. The SOI carrier substrate 135 of the SOI wafer can be removed by one or more of grinding, chemical mechanical polishing (CMP), and/or selective etching using an appropriate chemistry as shown in FIG. 3D. Removal of the SOI carrier substrate 135 exposes the lower surface 415 of the BOX layer 110 of the RF circuit device 100B. The lower surface 415 of the BOX layer 110 can then be coated with a protective coating layer 215 including a single material or combinations of materials including silicon nitride, polysilicon, and low K dielectrics to bind the parasitic surface charge on the BOX layer 110 and to provide a protective coating to prevent moisture ingress and provide physical protection of the RF circuit device 100B. Openings in this protective coating layer 215 (one of which is illustrated in FIG. 3E) are created using standard photolithography and etch technologies. Via holes 320 (one of which is illustrated in FIG. 3E) are then etched through the BOX layer 110. Multiple etch techniques can be used for the through BOX etch including reactive ion etch (RIE), inductively coupled plasma (ICP) etch, or wet chemical etch. The resultant through BOX via feature 320 is depicted in FIG. 3E. In some embodiments, etching through the protective coating layer 215 and through the BOX layer 110 to form the through BOX via feature 320 is performed in a single etch operation. Through BOX vias 340 are then formed in the through BOX via feature 320. Contacts 325 are then formed in electrical contact with the through BOX vias 340 on the lower surface of the protective coating layer 215 as shown in FIG. 3F. Through BOX vias 340 and contacts 325 may be formed by physical or chemical deposition processes, electroplating, or any metal deposition process known in the art. In some embodiments, through BOX vias 340 and contacts 325 are formed in a same metal deposition step. The contacts 325 are used to connect the elements of the RF circuit device 100B to outside circuit elements.

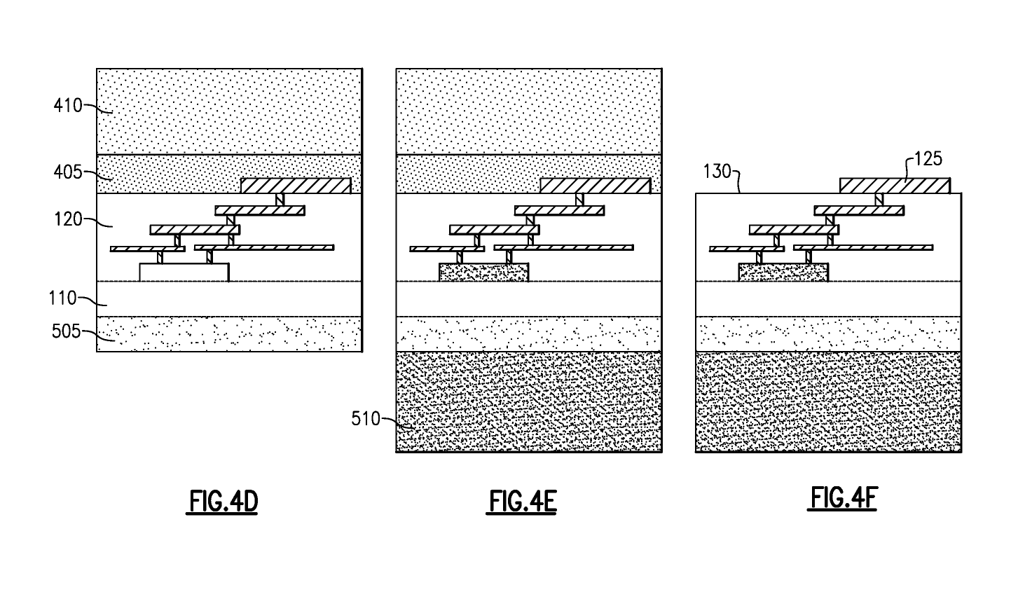

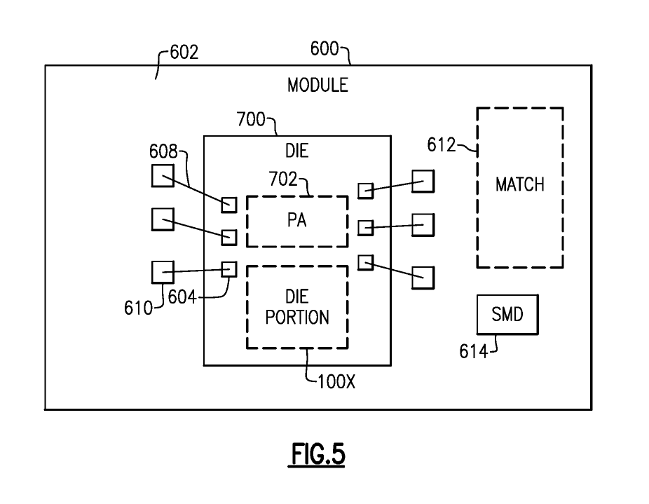

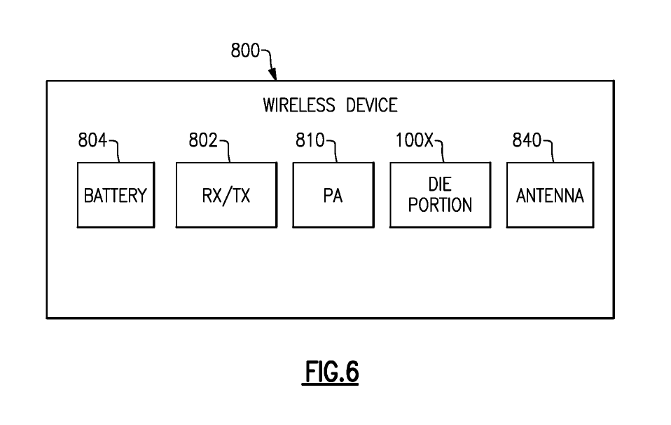

A third method disclosed herein uses a double layer transfer process. An example of a method used for this double layer transfer process is depicted in FIGS. 4A through 4F. The starting wafer in these figures has again been formed through standard front side SOI processing techniques as shown in FIG. 4A and includes RF circuit devices 100C similar to those illustrated in FIG. 1. The front side of the wafer is coated with a uniform, planar temporary adhesive 405 as illustrated in FIG. 4B. There are multiple types of appropriate temporary adhesive materials 405 that can vary between those that are UV sensitive, laser sensitive, or even thermally sensitive. These sensitivities are used during the subsequent removal of the temporary adhesive material 405. In some embodiments, the temporary adhesive material 405 is a bonding material such as WaferBOND® HT-10.10 temporary bonding material available from Brewer Science, Inc., Rolla, Mo. or any other temporary wafer bonding material known in the art.

A temporary carrier 410 is then bonded to the front side of the wafer with the temporary adhesive 405 as depicted in FIG. 4B. Types of temporary carriers 410 may include sapphire, borosilicate glass, fused silica, or even silicon wafers. If using a temporary adhesive 405 that it UV sensitive, a temporary carrier 410 that is clear or translucent to UV light may be utilized so that the temporary adhesive 405 can be uniformly degraded with exposure to UV light during the subsequent removal of the temporary adhesive material 405 and temporary carrier 410.

The SOI carrier substrate 135 portion of the SOI wafer is removed by one or more of grinding, chemical mechanical polishing (CMP), and/or selective etching using an appropriate chemistry as shown in FIG. 4C. Removal of the SOI carrier substrate 135 exposes the lower surface 415 of the BOX layer of the RF circuit device 100C. The lower surface 415 of the BOX layer 110 is then coated with a permanent adhesive layer 505. The permanent adhesive layer 505 may include a single material or combinations of materials including silicon nitride, polysilicon, and low K dielectric adhesives to bind the parasitic surface charge on the BOX layer 110, to provide a protective coating to prevent moisture ingress and to be used as an adhesive for permanent wafer bonding as shown in FIG. 4D. In some embodiments, epoxy may be utilized as a permanent adhesive. The permanent adhesive layer 505 can be patterned using standard photolithography techniques as needed to reduce stress and/or to assist in solvent extraction during wafer bonding. The SOI wafer is then permanently wafer bonded to a permanent carrier substrate 510 using existing standard wafer bonding tool sets. Multiple types of permanent carrier substrates 510 are available and include fused silicon, borosilicate glass, III-V materials, sapphire, high resistance silicon, and trap rich silicon. In some embodiments, the permanent carrier substrate 510 is directly bonded to the lower surface 415 of the BOX layer 110, for example, using an anodic bonding or a direct fusion bonding process.

The passive RF element(s) 125 of the RF circuit device 100C exhibit a lesser degree of capacitive coupling (if any) and/or a lesser degree of non-linear interaction with the permanent carrier substrate 510 than with the original SOI carrier substrate 135. The linearity and loss of the passive RF element(s) 125 of circuits can be improved with the careful selection of a low dielectric constant permanent adhesive layer 505 and permanent carrier substrate 510. The thickness of the permanent adhesive layer 505 can be modified to adjust the proximity of the passive RF element(s) 125 to the permanent carrier substrate 510 and thus can be used to optimize capacitive coupling between the passive RF element(s) 125 and the permanent carrier substrate 510. In some embodiments, the thickness of the adhesive 505 can range from about 4 μm to over about 60 μm, the BOX layer 110 thickness can range from about 0.1 μm to about 2 μm and the permanent carrier substrate 510 may range in thickness from about 500 μm to about 800 μm.

After the permanent carrier substrate 510 is bonded to the SOI wafer, the temporary carrier 410 can be removed, for example, by one or more of grinding, chemical mechanical polishing (CMP), chemical dissolution of the temporary adhesive 405 with appropriate wet or dry chemicals, and/or by thermal or UV breakdown of the temporary adhesive 405. Other methods of removing the temporary carrier 410 and temporary adhesive 405 may also be known to those of skill in the art.

Contacts, for example, solder balls (not shown) may be formed on the upper surface 130 of the interlayer dielectric material layer 120 or on the passive RF element(s) 125 to provide electrical contact between the elements of the RF circuit device 100C and external devices and/or circuit elements.

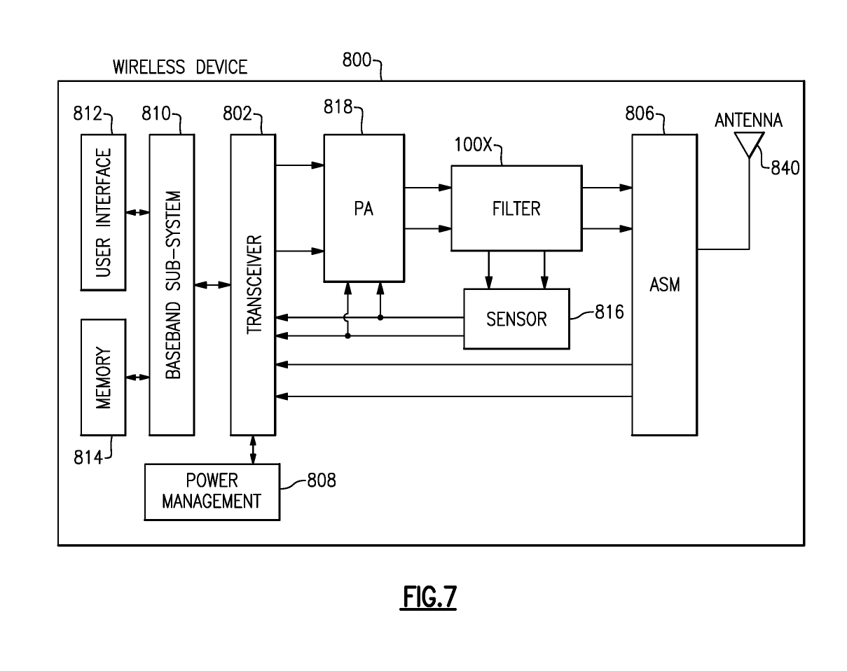

Embodiments of any one or more of RF circuit devices 100A, 100B, and 100C described herein can be implemented in a variety of different modules including, for example, a stand-alone coupler module, a front-end module, a module combining the coupler with an antenna switching network, an impedance matching module, an antenna tuning module, or the like. FIG. 5 illustrates one example of a module 600 that can include any of the embodiments or examples of the RF circuit devices 100A, 100B, and 100C discussed herein. RF circuit devices 100A, 100B, and 100C may be included in the module 600 as at least a portion of a die, illustrated at 100X. The Module 600 has a packaging substrate 602 that is configured to receive a plurality of components. In some embodiments, such components can include a die 700 having one or more featured as described herein. For example, the die 700 can include a PA circuit 702 and RF circuit devices 100X. A plurality of connection pads 604 can facilitate electrical connections such as wirebonds 608 to connection pads 610 on the substrate 602 to facilitate passing of various power and signals to and from the die 700.

In some embodiments, other components can be mounted on or formed on the packaging substrate 602. For example, one or more surface mount devices (SMDs) (614) and one or more matching networks (612) can be implemented. In some embodiments, the packaging substrate 602 can include a laminate substrate.

In some embodiments, the module 600 can also include one or more packaging structures to, for example, provide protection and facilitate easier handling of the module 600. Such a packaging structure can include an overmold formed over the packaging substrate 602 and dimensioned to substantially encapsulate the various circuits and components thereon.

It will be understood that although the module 600 is described in the context of wirebond-based electrical connections, one or more features of the present disclosure can also be implemented in other packaging configurations, including flip-chip configurations.

Embodiments of the RF circuit devices disclosed herein, optionally packaged into the modules 600, may be advantageously used in a variety of electronic devices. Examples of the electronic devices can include, but are not limited to, consumer electronic products, parts of the consumer electronic products, electronic test equipment, cellular communications infrastructure such as a base station, etc. Examples of the electronic devices can include, but are not limited to, a mobile phone such as a smart phone, a telephone, a television, a computer monitor, a computer, a modem, a hand held computer, a laptop computer, a tablet computer, an electronic book reader, a wearable computer such as a smart watch, a personal digital assistant (PDA), household equipment such as a microwave, a refrigerator, a washer, a dryer, or a washer/dryer, an automobile, a stereo system, a DVD player, a CD player, a digital music player such as an MP3 player, a radio, a camcorder, a camera, a digital camera, a portable memory chip, a health care monitoring device, a vehicular electronics system such as an automotive electronics system or an avionics electronic system, a peripheral device, a wrist watch, a clock, etc. Further, the electronic devices can include unfinished products.

FIG. 6 is a block diagram of a wireless device 800 including an RF circuit device according to certain embodiments. The wireless device 800 can be a cellular phone, smart phone, tablet, modem, communication network or any other portable or non-portable device configured for voice and/or data communication. The wireless device 800 includes an antenna 840 that receives and transmits power signals and an RF circuit device 100X that can use a transmitted signal for analysis purposes or to adjust subsequent transmissions. For example, the RF circuit device 100X can measure a transmitted RF power signal from the power amplifier (PA) 810, which amplifies signals from a transceiver 802. The transceiver 802 can be configured to receive and transmit signals in a known fashion. As will be appreciate by those skilled in the art, the power amplifier 810 can be a power amplifier module including one or more power amplifiers. The wireless device 800 can further include a battery 804 to provide operating power to the various electronic components in the wireless device.

FIG. 7 is a more detailed block diagram of an example of the wireless device 800. As shown, the wireless device 800 can receive and transmit signals from the antenna 840. The transceiver 802 is configured to generate signals for transmission and/or to process received signals. Signals generated for transmission are received by the power amplifier (PA) 818, which amplifies the generated signals from the transceiver 802. In some embodiments, transmission and reception functionalities can be implemented in separate components (e.g. a transmit module and a receiving module), or be implemented in the same module. The antenna switch module 806 can be configured to switch between different bands and/or modes, transmit and receive modes etc. As is also shown in FIG. 7, the antenna 840 both receives signals that are provided to the transceiver 802 via the antenna switch module 806 and also transmits signals from the wireless device 800 via the transceiver 802, the PA 818, the RF circuit device 100X, and the antenna switch module 806. However, in other examples multiple antennas can be used.

The wireless device 800 of FIG. 7 further includes a power management system 808 that is connected to the transceiver 802 that manages the power for the operation of the wireless device. The power management system 808 can also control the operation of a baseband sub-system 810 and other components of the wireless device 800. The power management system 808 provides power to the wireless device 800 via the battery 804 in a known manner, and includes one or more processors or controllers that can control the transmission of signals and can also configure the RF circuit device 100X based upon the frequency of the signals being transmitted, for example.

In one embodiment, the baseband sub-system 810 is connected to a user interface 812 to facilitate various input and output of voice and/or data provided to and received from the user. The baseband sub-system 810 can also be connected to memory 814 that is configured to store data and/or instructions to facilitate the operation of the wireless device, and/or to provide storage of information for the user.

The power amplifier 818 can be used to amplify a wide variety of RF or other frequency-band transmission signals. For example, the power amplifier 818 can receive an enable signal that can be used to pulse the output of the power amplifier to aid in transmitting a wireless local area network (WLAN) signal or any other suitable pulsed signal. The power amplifier 818 can be configured to amplify any of a variety of types of signal, including, for example, a Global System for Mobile (GSM) signal, a code division multiple access (CDMA) signal, a W-CDMA signal, a Long Term Evolution (LTE) signal, or an EDGE signal. In certain embodiments, the power amplifier 818 and associated components including switches and the like can be fabricated on GaAs substrates using, for example, pHEMT or BiFET transistors, or on a Silicon substrate using CMOS transistors.

Still referring to FIG. 7, the wireless device 800 can also include a RF circuit device 100X having one or more directional EM couplers for measuring transmitted power signals from the power amplifier 818 and for providing one or more coupled signals to a sensor module 816. The sensor module 816 can in turn send information to the transceiver 802 and/or directly to the power amplifier 818 as feedback for making adjustments to regulate the power level of the power amplifier 818. In this way the RF circuit device 100X can be used to boost/decrease the power of a transmission signal having a relatively low/high power. It will be appreciated, however, that the RF circuit device 100X can be used in a variety of other implementations.

In certain embodiments in which the wireless device 800 is a mobile phone having a time division multiple access (TDMA) architecture, the RF circuit device 100X can advantageously manage the amplification of an RF transmitted power signal from the power amplifier 818. In a mobile phone having a time division multiple access (TDMA) architecture, such as those found in Global System for Mobile Communications (GSM), code division multiple access (CDMA), and wideband code division multiple access (W-CDMA) systems, the power amplifier 818 can be used to shift power envelopes up and down within prescribed limits of power versus time. For instance, a particular mobile phone can be assigned a transmission time slot for a particular frequency channel In this case the power amplifier 818 can be employed to aid in regulating the power level one or more RF power signals over time, so as to prevent signal interference from transmission during an assigned receive time slot and to reduce power consumption. In such systems, the RF circuit device 100X can be used to measure the power of a power amplifier output signal to aid in controlling the power amplifier 818, as discussed above. The implementation shown in FIG. 7 is exemplary and non-limiting. For example, the implementation of FIG. 7 illustrates the RF circuit device 100X being used in conjunction with a transmission of an RF signal, however, it will be appreciated that various examples of the RF circuit device discussed herein can also be used with received RF or other signals as well.

The phraseology and terminology used herein is for the purpose of description and should not be regarded as limiting. As used herein, the term “plurality” refers to two or more items or components. The terms “comprising,” “including,” “carrying,” “having,” “containing,” and “involving,” whether in the written description or the claims and the like, are open-ended terms, i.e., to mean “including but not limited to.” Thus, the use of such terms is meant to encompass the items listed thereafter, and equivalents thereof, as well as additional items. Only the transitional phrases “consisting of and “consisting essentially of,” are closed or semi-closed transitional phrases, respectively, with respect to the claims. Use of ordinal terms such as “first,” “second,” “third,” and the like in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Having thus described several aspects of at least one embodiment, it is to be appreciated various alterations, modifications, and improvements will readily occur to those skilled in the art. Any feature described in any embodiment may be included in or substituted for any feature of any other embodiment. Such alterations, modifications, and improvements are intended to be part of this disclosure, and are intended to be within the scope of the invention. Accordingly, the foregoing description and drawings are by way of example only.

What is claimed is:

1. An electronic device comprising:
an active radio frequency (RF) circuit element integrated into a silicon-on-insulator (SOI) substrate;
a passive RF circuit element integrated into the SOI substrate; and
a carrier substrate including a dielectric material bonded to the SOI substrate.

2. The electronic device of claim 1 further comprising a dielectric material layer formed above the active RF circuit element and the buried oxide layer, the passive RF circuit element disposed on an upper surface of the dielectric material layer.

3. The electronic device of claim 2 wherein the passive RF circuit element is laterally offset from the active RF circuit element.

4. The electronic device of claim 3 wherein the dielectric material layer includes a plurality of interlayer dielectric material layers separating at least two layers of metal interconnects.

5. The electronic device of claim 3 wherein the carrier substrate is bonded to the dielectric material layer.

6. The electronic device of claim 5 further comprising an adhesive layer bonding the carrier substrate to the dielectric material layer.

7. The electronic device of claim 5 further comprising a dielectric coating disposed on a lower surface of the buried oxide layer.

8. The electronic device of claim 7 further comprising a conductive via disposed in the dielectric coating and the buried oxide layer and in electrical contact with the active RF circuit element and with a contact formed on a lower surface of the dielectric coating.

9. The electronic device of claim 3 wherein the carrier substrate is bonded to the buried oxide layer.

10. The electronic device of claim 9 wherein the carrier substrate is anodically bonded to buried oxide layer.

11. The electronic device of claim 1 wherein the dielectric material is selected from the group consisting of fused silicon, borosilicate glass, III-V materials, sapphire, and high resistance silicon.

12. The electronic device of claim 11 wherein the dielectric material is different from a material of a SOI carrier substrate upon which the electronic device was initially formed.

13. The electronic device of claim 1 incorporated into an RF system.

14. A method of forming an electronic device, the method comprising:
fabricating a silicon on insulator (SOI) device including an active radio frequency (RF) circuit element, a passive RF circuit element, a buried oxide layer, an interlayer dielectric material layer, and a semiconductor carrier substrate disposed on a lower surface of the buried oxide layer;
bonding a dielectric carrier substrate to an upper surface of the interlayer dielectric material layer;
removing the semiconductor carrier substrate from the SOI device;
forming a protective dielectric material layer on the lower surface of the buried oxide layer; and
forming a conductive via through the protective dielectric material layer and buried oxide layer, the conductive via electrically connecting the active RF circuit element to a contact formed on a lower surface of the protective dielectric material layer.

15. The method of claim 14 wherein the conductive via is formed through the buried oxide layer during fabrication of the SOI device and prior to removing the semiconductor carrier substrate from the SOI device.

16. The method of claim 14 wherein the conductive via is formed subsequent to removing the semiconductor carrier substrate from the SOI device.

17. The method of claim 16 wherein the conductive via is formed subsequent to forming the protective dielectric material layer.

18. The method of claim 17 wherein a conductive material of the conductive via is deposited in a same deposition step as the contact.

19. The method of claim 14 wherein bonding the dielectric carrier substrate to the upper surface of the interlayer dielectric material layer includes bonding the dielectric carrier substrate to the upper surface of the interlayer dielectric material layer with an adhesive material layer.

20. The method of claim 14 further comprising incorporating the electronic device into an RF system.

21. A method of forming an electronic device, the method comprising:
fabricating a silicon on insulator (SOI) device including an active radio frequency (RF) circuit element, a passive RF circuit element, a buried oxide layer, an interlayer dielectric material layer, and a semiconductor carrier substrate disposed on a lower surface of the buried oxide layer;
bonding a temporary carrier substrate to an upper surface of the interlayer dielectric material layer with a temporary adhesive;
removing the semiconductor carrier substrate from the SOI device;
bonding a dielectric carrier substrate to a lower surface of the buried oxide layer; and
removing the temporary carrier substrate and temporary adhesive from the SOI device.

22. The method of claim 21 wherein bonding the dielectric carrier substrate to the lower surface of the buried oxide layer includes bonding the dielectric carrier substrate to the lower surface of the buried oxide layer with an adhesive.

23. The method of claim 21 wherein bonding the dielectric carrier substrate to the lower surface of the buried oxide layer includes anodically bonding the dielectric carrier substrate to the lower surface of the buried oxide layer.

24. The method of claim 21 wherein bonding the dielectric carrier substrate to the lower surface of the buried oxide layer includes direct fusion bonding the dielectric carrier substrate to the lower surface of the buried oxide layer.

25. The method of claim 21 further comprising incorporating the electronic device into an RF system.
